(19) United States
(12) Patent Application Publication
(10) Pub. No.: US 2013/0074901 A1
(43) Pub. Date: Mar. 28, 2013

(54) COMPOSITIONALLY GRADED DILUTE GROUP III-V NITRIDE CELL WITH BLOCKING LAYERS FOR MULTIJUNCTION SOLAR CELL

(71) Applicant: ROSESTREET LABS ENERGY, INC., Phoenix, AZ (US)

(72) Inventors: Wladyslaw WALUKIEWICZ, Kensington, CA (US); Kin Man YU, Lafeyette, CA (US)

(73) Assignee: ROSESTREET LABS ENERGY, INC., Phoenix, AZ (US)

(21) Appl. No.: 13/623,520

(22) Filed: Sep. 20, 2012

Related U.S. Application Data
(60) Provisional application No. 61/538,049, filed on Sep. 22, 2011.

(51) Int. Cl. H01L 31/0687; H01L 31/068; H01L 31/042

(52) U.S. Cl. 136/244; 136/252; 136/262

(57) ABSTRACT

A dilute Group III-V nitride solar cell is provided for use in a multijunction solar cell having a p-n junction formed by p-type and n-type layers of dilute Group III-V nitride material, such as GaNAs. Blocking layers of a group III-V ternary alloy are formed on opposing surfaces of the p-n junction to improve the electron and hole collection efficiency of the p-n junction by preventing the flow of electrons and holes, respectively, into the adjacent layers of the multijunction solar cell in certain directions. The III-V nitride solar cell is current matched to other solar cells of the multijunction solar cell. The III-V nitride solar cell may possess a bandgap of approximately 1.0 eV to serve as one junction of the multijunction solar cell. The p-type and n-type layers may further have compositionally graded nitrogen concentrations to provide an electric field for more efficient charge collection.

### CROSS-REFERENCE To RELATED APPLICATIONS

This application claims the benefit of priority of U.S. Provisional Pat. Application Ser. No. 61/538,049, filed on Sep. 22, 2011, entitled “Compositionally Graded Dilute Group III-V Nitride Cell with Blocking Layers for Multijunction Solar Cell,” which is incorporated by reference herein in its entirety.

### STATEMENT OF GOVERNMENTAL INTEREST

The invention described and claimed herein was made in part utilizing funds supplied by the U.S. Department of Energy under Contract No. DE-AC02-05CH11231. The government has certain rights in this invention.

### BACKGROUND OF THE INVENTION

1. Field of the Invention

The disclosure relates to solar cells and, more particularly, to a multijunction solar cell including a dilute Group III-V nitride solar cell with graded composition and blocking layers.

2. Background Discussion

Solar or photovoltaic cells are semiconductor devices having P-N junctions which directly convert radiant energy of sunlight into electrical energy. Conversion of sunlight into electrical energy involves three major processes: absorption of sunlight into the semiconductor material; generation and separation of positive and negative charges creating a voltage in the solar cell; and collection and transfer of the electrical charges through terminals connected to the semiconductor material. A single depletion region for charge separation typically exists in the P-N junction of each solar cell.

Current traditional solar cells based on single semiconductor material have an intrinsic efficiency limit of approximately 31%. A primary reason for this limit is that a semiconductor has a specific energy gap that can only absorb a certain fraction of the solar spectrum with photon energies ranging from 0.4 to 4 eV.

A primary reason for this limit is that no one material has been found that can perfectly match the broad ranges of solar radiation, which has a usable energy in the photon range of approximately 0.4 to 4 eV. Light with energy below the bandgap of the semiconductor will not be absorbed and converted to electrical power. Light with energy above the bandgap will be absorbed, but electron-hole pairs that are created quickly lose their excess energy above the bandgap in the form of heat. Thus, this energy is not available for conversion to electrical power.

Solar cells with higher efficiencies can be achieved by using stacks of solar cells made of semiconductors with different band gaps, thereby forming a series of solar cells, referred to as “multijunction,” “cascade,” or “tandem” solar cells. Multijunction solar cells are made by connecting a plurality (e.g., two, three, etc.) P-N junction solar cells in series, thereby achieving more efficient solar cells over single P-N junction solar cells. Tandem cells are typically formed using higher gap materials in the top cell to convert higher energy photons, while allowing lower energy photons to pass down to lower gap materials in the stack of solar cells. The bandgaps of the solar cells in the stack are chosen to maximize the efficiency of solar energy conversion, where tunnel junctions are used to series-connect the cells such that the voltages of the cells sum together.

For example, referring to FIG. 1, a known multijunction solar cell 100 is illustrated having three P-N junction solar cells 102, 104 and 106 connected in series. Tunnel junctions 108 are formed to interconnect the individual cells 102, 104 and 106. Each of the cells 102, 104 and 106 are formed to possess different bandgaps with higher bandgap materials used in the top cell and lower bandgap materials used in the bottom cell. For example, the top cell 102 has been formed of a GaInP semiconductor alloy having a 1.8 eV bandgap, the middle cell 104 formed of a GaAs semiconductor alloy having a 1.4 eV bandgap, and the bottom cell 106 formed of a Ge semiconductor material having a 0.7 eV bandgap. Thus, each of the individual solar cells 102, 104 and 106 will absorb different portions of the solar spectrum of the sunlight 110 passing through the multijunction solar cell 100.

Theoretically, the conversion efficiencies of a multijunction solar cell will increase with each additional P-N junction solar cell having a different bandgap that is added to the multijunction solar cell. However, conventional multijunction solar cells and their corresponding conversion efficiencies have been limited to three junctions, such as those illustrated in FIG. 1, due to the unavailability of a lattice-matched 1 eV subcell and the inability to maintain required current levels in a fourth added P-N junction solar cell based on the loss of holes and electrons to neighboring layers of the multijunction solar cell.

Ga_{1-y}In_{y}NₓAs₁₋ₓ alloys were proposed for the fourth junction. The alloy with x=0.03 and y=0.09 has a gap of 1 eV required for the 4^{th} junction and is lattice matched to GaAs. Practical attempts to incorporate such a 4^{th} junction into existing triple junction (Ge/GaAs/GaInP) were not successful because the GaInNAs junction produced too small current that could not be matched with the current produced by three other junctions. Attempts to increase the current by decreasing the band gap reduced the open circuit voltage. The reason for the poor performance of the previously designed 4^{th} cells is a low electron mobility and a short diffusion length of minority electrons in p-type layer.

### SUMMARY

The disclosure relates to solar cells and, more specifically, to a multijunction solar cell including a dilute Group III-V nitride solar cell with graded composition and electron and/or hole blocking layers forming one of the junctions of the multijunction solar cell for improved solar cell performance.

In accordance with one or more embodiments, a multijunction solar cell is provided comprising a plurality of P-N junction solar cells connected in series, in which one of the P-N junction solar cells comprises a p-n junction based on dilute III-V nitride materials e.g. GaNₓAs₁₋ₓ or In_{y}G_{1-y}aNₓAs₁₋ₓ or GaNₓSb_{z}As_{1-x-z} with x in the range of 0.01-0.05, y in the range 0 to 0.15 and z in the range 0 to 0.15 and a pair of contact blocking layers positioned on opposite surfaces of the p-n junction. The contact blocking layers improve the electron and hole collection efficiency of the p-n junction by preventing the flow of electrons and holes, respectively, into the adjacent layers of the multijunction solar cell in certain directions, depending upon the orientation of the p-n junction, so that electrons may only flow through the dilute III-V nitride solar cell in one direction while holes may only flow through the dilute III-V nitride solar cell in the opposite direction. The charge collection efficiency is improved by compositional grading n and/or the p type side of the junction. The lattice matching with the other component of the tandem cells requires that y=3x and z=3x. In one or more embodiments, the dilute III-V nitride solar cell is formed such that the current it produces when exposed to solar radiation is matched to the current produced by the other solar cells of the multijunction solar cell, such that current matching is achieved between each of the solar cells of the multijunction solar cell for improved solar cell performance. In one or more embodiments, the dilute III-V nitride solar cell is formed to possess a bandgap of approximately 1.0 eV.

In accordance with one or more embodiments, the p-n junction of the dilute III-V nitride solar cell of the multijunction solar cell comprises corresponding p-type and n-type layers of GaInNAs, and the contact blocking layers of the dilute III-V nitride solar cell comprise at least one of AlGaAs or InGaP or another group III-V ternary alloy. In one or more embodiments, at least one of the contact blocking layers are lattice matched to a desired band gap of the GaInNAs p-n junction layers of the dilute III-V nitride solar cell (i.e., the GaInNAs absorber layers). In one or more embodiments, the composition of one of the contact blocking layers are tuned so that its conduction band is aligned with the lower sub-band of the GaInNAs or GaNAsSb absorber layers. In one or more embodiments, the GaInNAs or GaNAsSb emitter and absorber layers of the dilute III-V nitride solar cell may further have compositionally graded concentrations of nitrogen and In in In_{y}G_{1-y}aNₓAs₁₋ₓ or N and Sb in GaNₓSb_{z}As_{1-x-z} to provide an electric field for electron and holes so that efficient charge collection can be achieved.

Many other features and embodiments disclosed herein will be apparent from the accompanying drawings and from the following detailed description.

### DRAWINGS

The above-mentioned features and objects of the present disclosure will become more apparent with reference to the following description taken in conjunction with the accompanying drawings wherein like reference numerals denote like elements and in which:

FIG. 1 is a block diagram representation of a prior art conventional three junction multijunction solar cell.

FIG. 2 is a block diagram representation of a four junction multijunction solar cell in accordance with one or more embodiments of the present disclosure.

FIG. 3 is a graphical illustration of a calculated band diagram for one embodiment of the multijunction solar cell shown in FIG. 1, in accordance with one or more embodiments of the present disclosure.

FIG. 4 is a block diagram representation of a fourth junction of a multijunction solar cell in accordance with one or more embodiments of the present disclosure.

FIG. 5 is a block diagram representation of a fourth junction of a multijunction solar cell using dilute group III-V nitride material with a graded Nitrogen composition (N composition grading from x=0 to ˜0.24 in the p type layer and from 0.24 at the junction to 0 in the n-type layer) in accordance with one or more embodiments of the present disclosure. Note that the composition of In in GaInNAs or Sb in GaNSbAs would change accordingly with the N composition so that these layers are lattice matched with the GaAs substrate.

FIG. 6 is a graphical illustration of a calculated band diagram for one embodiment of the fourth junction of a multijunction solar cell having graded compositions as shown in FIG. 5.

FIG. 7A are comparisons of the calculated electric field, E in Volt per cm as a function of distance from the surface of one embodiment of the fourth junction of a multijunction solar cell having non-graded and graded compositions as in FIG. 4 and FIG. 5, respectively in accordance with one or more embodiments of the present disclosure. FIG. 7B is a replot of FIG. 7A in expanded scale of the y-axis to illustrate the strong field of the structure with graded composition. Note that in the design with graded N composition, large fields in the both the absorber and emitter layers assist the collection of carriers.

FIG. 8 is a block diagram representation of another fourth junction of a multijunction solar cell using a graded Nitrogen composition, p-type absorber layer in accordance with one or more embodiments of the present disclosure.

FIG. 9 is a graphical illustration of a calculated band diagram for one embodiment of the fourth junction of a multijunction solar cell of FIG. 8.

### DETAILED DESCRIPTION

In general, the present disclosure relates to a multijunction solar cell including one of the solar cells formed from dilute Group III-V nitride materials with graded Nitrogen composition, lattice matched to the bottom cell materials (e.g. Ge) surrounded by contact blocking layers for improved solar cell performance. More particularly, the present disclosure relates to a junction (i.e., solar cell) of a multijunction solar cell that comprises graded composition dilute Group III-V nitride materials surrounded by corresponding contact blocking layers to form a solar cell having a bandgap of approximately 1.0 eV that is current matched to the other solar cells of the multijunction solar cell.

Conventionally, the development of a multijunction solar cell in which one of the sub-cells possesses a bandgap of approximately 1.0 eV has been a challenge. It has been discovered that the substitution of small amount of nitrogen in a Group III-V semiconductor alloy (such as GaAs, InGaAs, GaAsSb, or GaAsP) splits the conduction band of the alloy into a higher conduction band (E₊) and a lower subband (E₋). The gap between the valence band the lower subband E₋ represent the reduced band gap and can be utilized for light absorption in the 0.9-1.4 eV energy range. Hence dilute group III-V nitride semiconductor is a good candidate material for the 1.0 eV bandgap subcell material. Previous reports on Group III-V nitride semiconductor solar cells resulted in low open circuit voltage (V_{OC}) readings, e.g. 0.3-0.4 eV, and low current. The low V_{OC} readings in prior devices likely occurred either because of non-ideal band separation or the lack of blocking of holes and electrons in the n- and p-layer, respectively these carriers “escape” to the “wrong” contact layer. The low current can be attributed to the low electron mobility in the E band (or the new conduction band in the dilute nitride layer) so that the diffusion length of carriers generated in the absorber layer are not able to reach the contact to be collected. The present inventors have solved these issues that enable solar cells formed of such materials to function as a 1.0 eV subcell current matched to other cells in a multijunction solar cell. Certain embodiments of the present disclosure will now be discussed with reference to the aforementioned figures, wherein like reference numerals refer to like components.

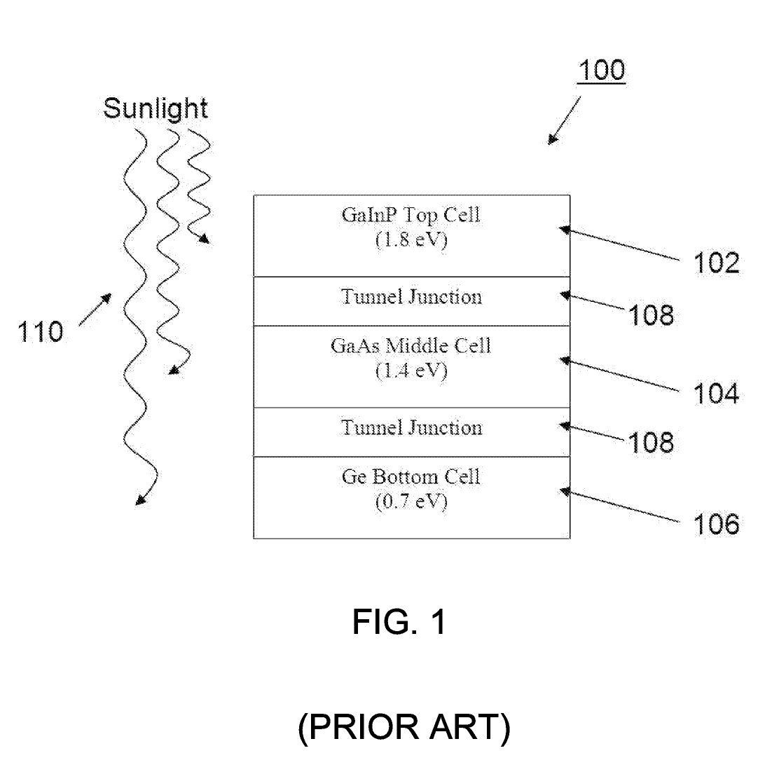

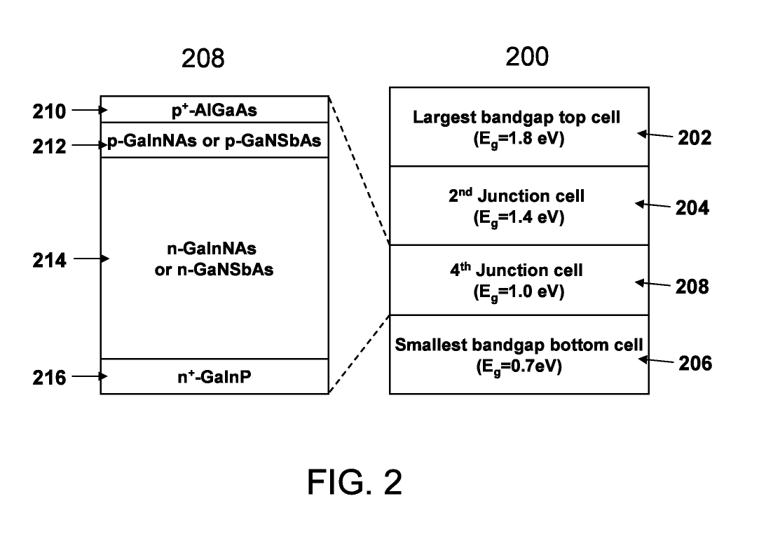

Referring now to FIG. 2, a block diagram illustration of a multijunction solar cell 200 (a four junction solar cell in this example) is shown generally in accordance with one or more embodiments of the present disclosure. In one or more embodiments, one of the solar cells of multijunction solar cell 200 is a dilute Group III-V nitride solar cell 208 comprising a p-n junction based on layers 212 and 214 of dilute Group III-V nitride alloys or materials, wherein one of the layers 212 or 214 is an n-type material formed on one side of the P-N junction and the other of the layers 212 or 214 is a p-type material is formed on the other side of the P-N junction. In one or more embodiments, p-n junction layers 212 and 214 comprise respective layers of Ga_{1-y}In_{y}NₓAs₁₋ₓ or GaNₓAs_{1-x-z}Sb_{z} where y˜3x or z˜3x for lattice matching to the bottom cell material (e.g. Ge). In the particular embodiment illustrated in FIG. 1, layer 212 is formed as p-GaInNAs or p-GaNSbAs and layer 214 is formed as n-GaInNAs or n-GaNSbAs (hereafter referred to as GaNAs for simplicity). While it is understood that the order of these p-type and n-type layers could be reversed for different applications. GaNAs p-n junction layers 212 and 214 may also be referred to herein as GaNAs absorber layers 212 and 214. Other Group III-V nitride alloys that have similar properties (such as AlGaNAs, GaNAsP) can also be used as the absorber layers 212 and 214.

In one or more embodiments, a pair of contact blocking layers 210 and 216 are positioned on opposite surfaces of the p-n junction. Contact blocking layers 210 and 216 improve the electron and hole collection efficiency of the p-n junction by preventing the flow of electrons and holes, respectively, into the adjacent layers of the multijunction solar cell 200 in certain directions, depending upon the orientation of the p-n junction of dilute Group III-V nitride solar cell 208, so that electrons may only flow through the dilute Group III-V nitride solar cell 208 in one direction while holes may only flow through the solar cell 208 in the opposite direction. Contact blocking layers 210 and 216 may be formed of any material that provides electron or hole blocking due to mismatch in the conduction band and valence band edge alignment between these layers and the new conduction band of the dilute nitride layer. The various layers 210, 212, 214 and 216 of the dilute Group III-V nitride solar cell 208 are illustrated in an enlarged view in FIG. 2 and are positioned within the multijunction solar cell 200 as indicated by the dashed lines.

In one or more embodiments, contact blocking layers 210 and 216 are lattice matched to the GaNAs (or InGaNAs) absorber layers 212 and 214 of dilute Group III-V nitride solar cell 208. In one or more embodiments, the contact blocking layers 210 and 216 comprise an alloy of either AlGaAs or InGaP. In one or more embodiments, one of the layers 210 and 216 comprises AlGaAs while the other of the layers 210 and 216 comprises InGaP, depending upon the direction of the p-n junction of dilute Group III-V nitride solar cell 208 and whether blocking layers 210 and 216 are being utilized to block the passage of either holes or electrons.

When holes and electrons are created in the GaNAs p-n junction absorber layers 212 and 214 upon exposure to solar radiation, it is desirable that the holes and electrons travel across the p-n junction between layers 212 and 214 through the valence band and the lower conduction band, respectively of the layers 212 and 214 to generate the resultant current in the dilute Group III-V nitride solar cell 208. The contact blocking layers 210 and 216 electrically block the passage of electron and holes generated in 212 and 214, respectively. In one or more embodiments, the composition of the GaNAs p-n junction absorber layers 212 and 214 and the contact blocking layers 210 and 216 are tuned to align the valence band and the conduction band of the contact blocking layers 210 and 216 with those of the GaNAs p-n junction absorber layers 212 and 214, respectively, while having a large mismatch in the conduction band in 210 and the valence band in 216.

In one or more embodiments, Indium (In) or Antimony (Sb) may be added to at least one of the absorber layers 212 and 214 so as to form GaInNAs or GaNSbAs layers in order to improve the lattice parameters matching of the materials, which improves the overall quality of the material and reduces material-based defects that could occur from routine usage and testing that could otherwise harm the efficiency of the multijunction solar cell 200. In one or more embodiments, the proportion of Nitrogen (N) to Indium (In) or Antimony (Sb) in layers 212 and 214 is selected to have a ˜1:3 ratio in order to yield optimal results and to compensate for the Nitrogen-induced contraction of the lattice parameter caused by the presence of Nitrogen in a compound.

In one or more embodiments, the dilute Group III-V nitride solar cell 208 is formed such that the current it produces when exposed to solar radiation is matched to the current produced by the other solar cells of the multijunction solar cell 200. By current matching the dilute Group III-V nitride solar cell 208 with the other solar cells of the multijunction solar cell 200, the respective voltages generated by each of the solar cells of the multijunction solar cell 200 will add together resulting in a larger overall voltage output for improved solar cell performance.

In one or more embodiments, the dilute Group III-V nitride solar cell 208 is formed to possess a bandgap of approximately 1.0 eV. In one or more embodiments, as illustrated in FIG. 2, the multijunction solar cell 200 includes four p-n junction solar cells 202, 204, 208 and 206 connected in series. Tunnel junctions (not shown) are formed to interconnect the individual solar cells 202, 204, 208 and 206. Each of the solar cells 202, 204, 208 and 206 are formed to possess different bandgaps with higher bandgap materials used in the top cell and lower bandgap materials used in the bottom cell. For example, the top cell 202 has the largest bandgap (e.g., a 1.8 eV bandgap, such as those formed by GaInP semiconductor alloys), the cell 204 second from the top has the second largest bandgap (e.g., a 1.4 eV bandgap, such as those formed by GaAs semiconductor alloys), the dilute Group III-V nitride solar cell 208 possesses a bandgap of approximately 1.0 eV (GaInNAs or GaNAs with N composition of ˜3%), and the bottom cell 206 has the smallest bandgap (e.g., a 0.7 eV bandgap, such as those formed by Ge). Thus, each of the individual solar cells 202, 204, 208 and 206 will absorb different portions of the solar spectrum of sunlight passing through the multijunction solar cell 200. While the specific different bandgaps of 1.8 eV, 1.4 eV, 1.0 eV and 0.7 eV are described in the preceding example, it is understood that solar cells with other bandgaps may be utilized in conjunction with the dilute Group III-V nitride solar cell 208 having a bandgap of approximately 1.0 eV as long as they are similarly current matched.

In one or more embodiments, the nitrogen composition in dilute Group III-V nitride solar cell 208 can be tuned to a bandgap of 0.8-1.4 eV so that it can be used as part of a multijunction cell with 2 to 5 junctions for optimum efficiency.

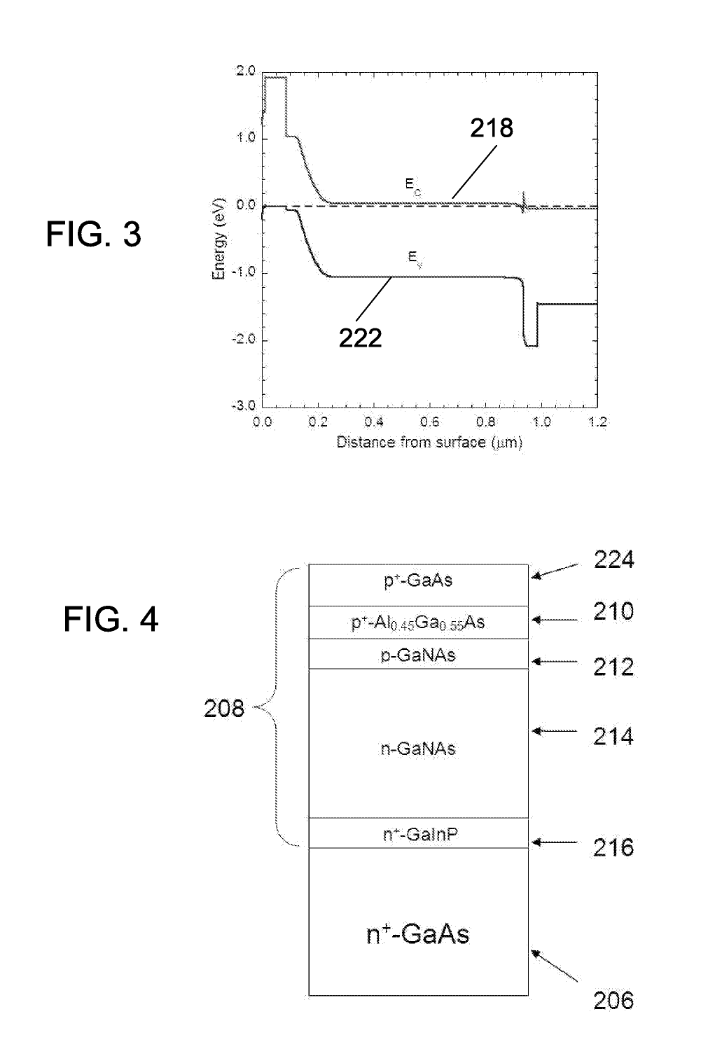

Referring now to FIG. 3, a graphical illustration of the calculated band diagram for one specific embodiment of the dilute Group III-V nitride solar cell 208 of FIG. 2. In this representative example, a 100 nm GaInP blocking layer 216 having an n⁺ doping>1×10¹⁹ cm⁻³ is formed on the bottom cell 206 (e.g., an n⁺ GaAs substrate layer). A 400 nm n-type GaNAs layer 214 that is Te doped (with electron concentration 1×10¹⁶−2×10¹⁷ cm⁻³) is formed on the n⁺ GaInP blocking layer 216, and a 100 nm p-type GaNAs layer 212 that is Zn doped 1×10¹⁸ cm⁻³ is formed on the n-type GaNAs layer 214. Finally, a 50 nm p⁺ Al_{0.45}Ga_{0.55}As blocking layer 216 is formed on the p-type GaNAs layer 212.

The calculated band diagram of FIG. 3 illustrates plots for the conduction band (E_{C}) 218 (also called lower subband E₋ or intermediate band formed as a result of the anticrossing interaction between the N states and the GaAs conduction band), and the valence band (E_{V}) 222. The x-axis of the calculated band diagram represents the distance from the surface of the structure in FIG. 2 in micron while the y-axis represents an energy measurement reading in units of eV (electron-volts) measured with respect to the Fermi energy level. The conduction band (E_{C}) 218 represents the energy band with empty states for electron conduction to occur, and the slope of the conduction band (E_{C}) 218 can reveal the rate of electron flow or charge transport throughout the dilute Group III-V nitride solar cell 208. Similarly, the valence band (E_{V}) 222 represents the energy band that is filled with electrons or with empty states for hole conduction, and the slope of the valence band (E_{V}) 222 can reveal the rate of hole flow or charge transport throughout the dilute Group III-V nitride solar cell 208. As can be seen in FIG. 3, the slope of both plots 218 and 222 show the electrons being repelled from the surface whereas holes are being drawn to the surface.

Referring now to FIG. 4, in one or more embodiments, the dilute Group III-V nitride solar cell 208 may be formed with a protective layer 224, such as p⁺ GaAs or the like, deposited on top of the contact blocking layer 210 for providing a protective covering over the other layers and to prevent the blocking layer 210 from oxidizing, especially if the blocking layer 210 is made from AlGa_{1-y}As with y>0.25. Protective layer 224 may also function as a low resistance contact. The protective layer 224 may usually comprise of n-type or p-type GaAs, depending on the desired configuration of the various layers of multijunction solar cell 200 for desired operation characteristics. In one or more embodiments, the protective layer 224 may optionally be deposited using known deposition techniques at a thinner thickness compared to the other layers of multijunction solar cell 200.

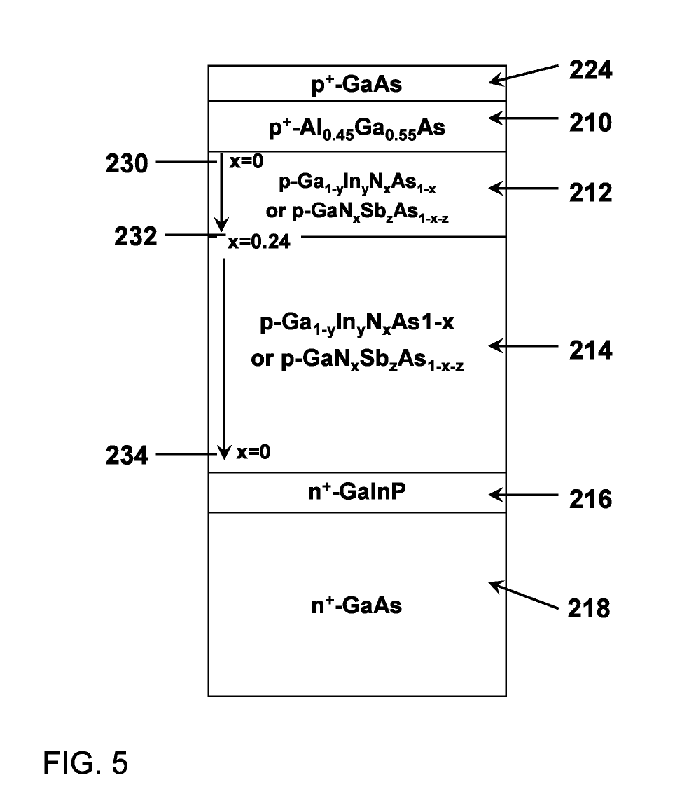

In one or more embodiments, the nitrogen concentration x in at least one or both of the GaNₓAs absorber layers 212 and 214 of the p-n junction of the dilute Group III-V nitride solar cell 208 can be compositionally graded in order to improve the performance of the multijunction solar cell 200, as illustrated in FIG. 5. Either or both of the GaNₓAs absorber layers 212 and 214 can be graded from a higher nitrogen concentration in one portion 232 of the GaNₓAs absorber layer 212 or 214 to a lower nitrogen concentration in another portion 230 or 234 of the same GaNₓAs absorber layer 212 or 214. For example, within the GaNAs layer 214, the N concentration decreases from x=0.024 near the interface between GaNₓAs₁₋ₓ layer 214 and GaNAs layer 212 to x=0.0 near the interface between GaNₓAs₁₋ₓ layer 214 and the GaInP blocking layer 216. In one or more embodiments, the portions of the GaNAs layers 212 and 214 closest to their junction will have the highest concentration of nitrogen. By compositionally grading at least one of the GaNAs absorber layers 212 and 214, an additional potential is created that drives holes toward the p contact 210, thereby increasing cell current.

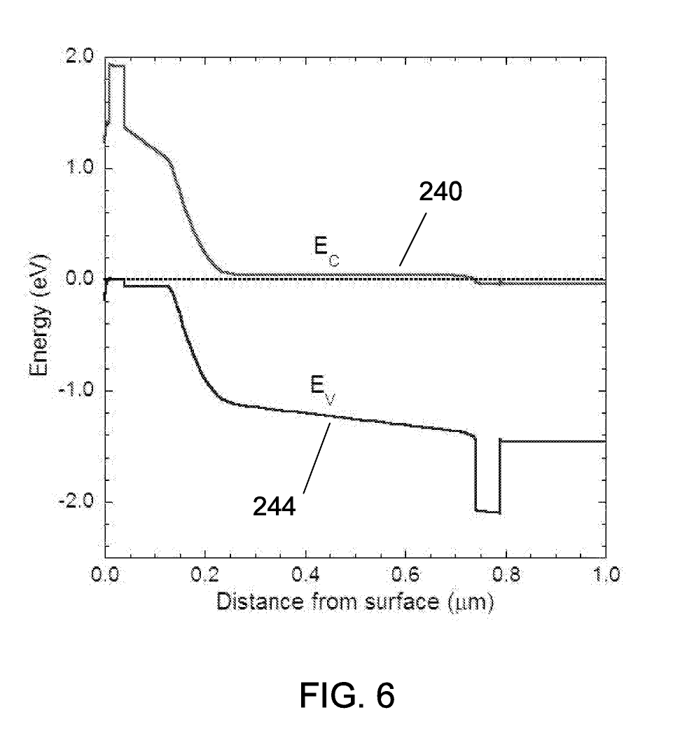

Referring now to FIGS. 6, a graphical illustration of the calculated band diagram for a specific embodiment of the dilute Group III-V nitride solar cell 208 with N composition grading of FIG. 5. In this representative example, a 100 nm GaInP blocking layer 216 having an n⁺ doping>1×10¹⁹ cm⁻³ is formed on the bottom cell 206 (e.g., an n⁺ Ge or GaAs substrate layer). An 600 nm n-type GaNAs layer 214 that is Te doped from 1×10¹⁶ to 2×10¹⁷ cm⁻³ is formed on the n⁺ GaInP blocking layer 216. In the structure of FIG. 5, the 600 nm n-type GaNAs layer 214 has its nitrogen concentration graded from x=0.024 near the interface between GaNₓAs₁₋ₓ layer 214 and layer 212 to x=0.0 near the interface between GaNₓAs₁₋ₓ layer 214 and GaInP blocking layer 216. A 100 nm p-type GaNAs layer 212 that is Zn doped 1×10¹⁸ cm⁻³ is formed on the n-type GaNAs layer 214. This p-type layer is also compositionally graded with x=0.024 at the p-n junction 232 and x=0 at the interface 230 between 212 and the AlGaAs blocking layer 210. A 50 nm p⁺ Al_{0.45}Ga_{0.55}As blocking layer 210 is formed on the p-type GaNAs layer 212. Finally, a <20 nm p⁺ GaAs protective layer 224 having an approximately 1×10¹⁹ cm⁻³ doping is formed over the blocking layer 110.

As illustrated in FIGS. 6, holes in GaNAs layer 214 and electron in the p-GaNAs layer 212 are blocked from substrate 218 and top contact 224, respectively. When comparing the band diagrams of the graded structure, shown in FIG. 6, with those of the non-graded structure, shown in FIG. 3, it can be seen that the valence band (E_{V}) 244 and conduction band (E_{C}) 240 of the graded structure has a greater slope in the absorber layer 214 and 212, respectively than the corresponding the valence band (E_{V}) 222 and conduction band (E_{C}) 218 of the non-graded structure, thereby showing the additional potential created in the graded structure that drives holes and electrons toward the p-n junction.

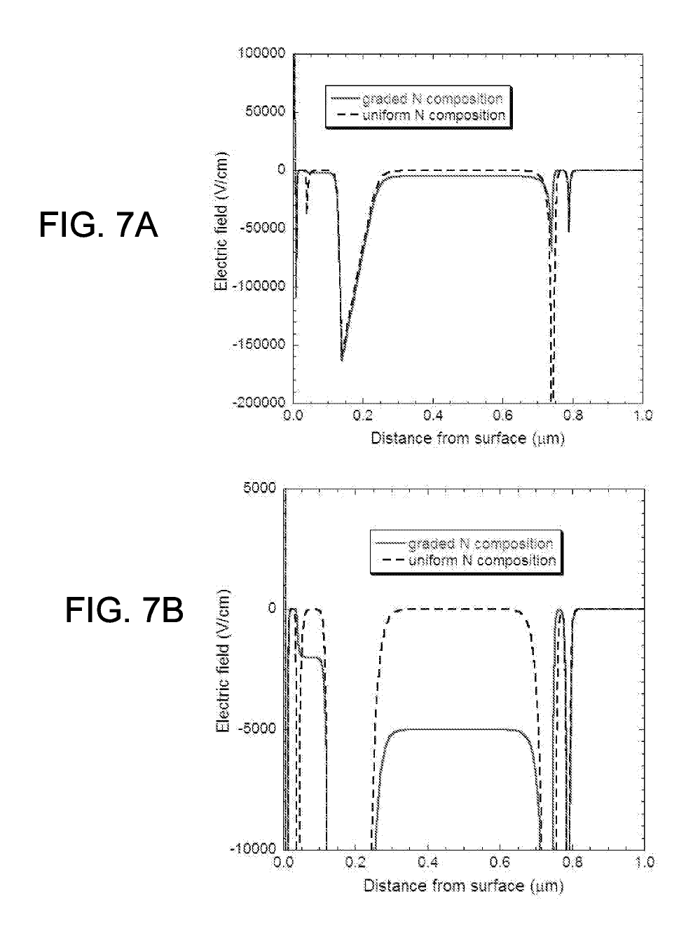

Referring now to FIG. 7A, a comparison of the calculated electric field, E in Volt per cm as a function of distance from the surface of one embodiment of the fourth junction of a multijunction solar cell having non-graded and graded compositions as in FIG. 4 and FIG. 5, respectively in accordance with one or more embodiments of the present disclosure is illustrated. FIG. 7B is a replot of FIG. 7A in expanded scale of the y-axis to illustrate the strong field of the structure in the absorber layers 212 and 214 with graded composition.

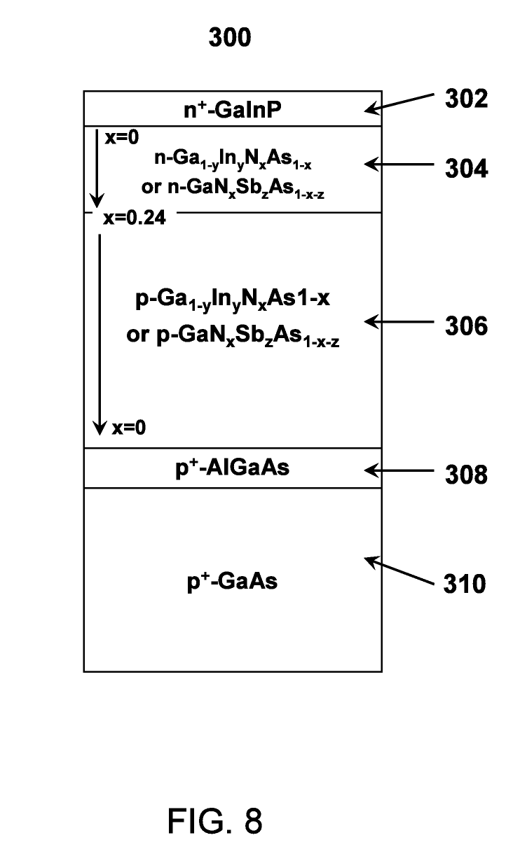

Referring now to FIG. 8, a dilute Group III-V nitride solar cell 300 formed in accordance with one or more embodiments is illustrated in which the direction of the p-n junction is reversed when compared to dilute Group III-V nitride solar cell 208, but dilute Group III-V nitride solar cell 300 would be formed within a corresponding multijunction solar cell 200 in which the direction of all of the other p-n junctions of the other solar cells would be similarly situated. In one representative example, a 50 nm AlGaAs blocking layer 308 having a p⁺ doping>1×10¹⁹ cm⁻³ is formed on a layer 310 of the bottom cell 206 (e.g., a p⁺ Ge or GaAs substrate layer). An 600 nm p-type GaNAs layer 306 that is Zn doped 1×10¹⁶ to 5×10¹⁷ cm⁻³ is formed on the AlGaAs blocking layer 308, and a 100 nm n-type GaNAs layer 304 that is Te doped 1×10¹⁸ cm⁻³ is formed on the p-type GaNAs layer 306. In the structure of FIG. 8, both the 600 nm p-type GaNAs layer 306 and 100 nm n-type GaNAs layer 304 have their nitrogen concentration graded from x=0.024 near the interface between GaNₓAs₁₋ₓ layer 306 and layer 304 to x=0.0 near the interface between GaNₓAs₁₋ₓ layer 306 and AlGaAs (308) and GaInP (302) blocking layers. Finally, a 50 nm n⁺ GaInP blocking layer 302 is formed on the n-type GaNAs layer 304. It is understood that the various materials, thicknesses and dopings can be altered according to known solar cell design preferences.

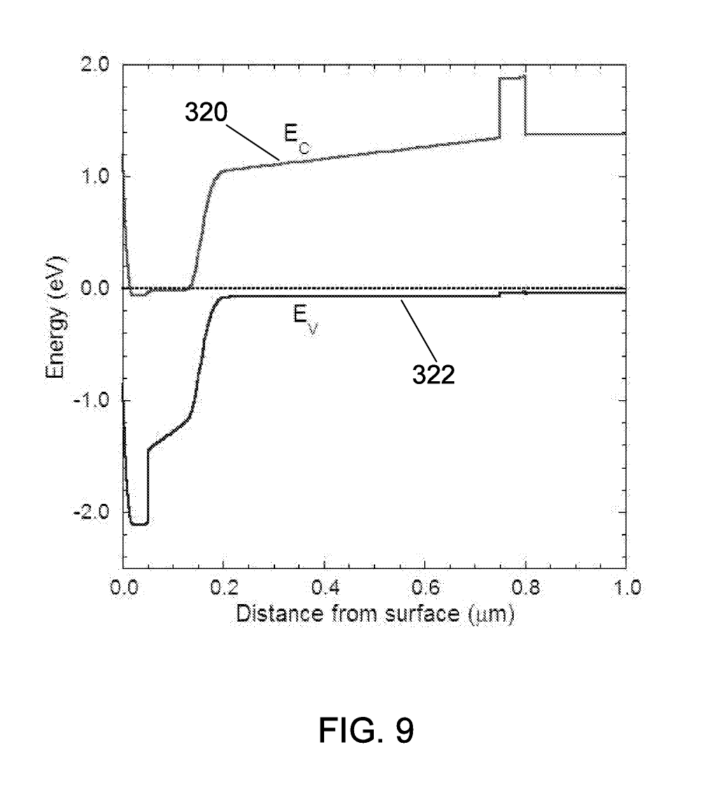

Referring now to FIG. 9, a graphical illustration of the calculated band diagram for the specific embodiment of the dilute Group III-V nitride solar cell 300 described above is illustrated. It can be seen from the band diagrams that the conduction band (E_{C}) 320 and valence band (E_{V}) 322 of the graded structure have a greater slope in the absorber layers than a corresponding non-graded structure, thereby showing the additional potential created in the graded structure that drives electrons toward the p-n junction.

In accordance with one or more embodiments, a multijunction solar cell is provided comprising a plurality of p-n junction solar cells connected in series, in which one of the solar cells comprises a dilute III-V nitride solar cell is formed to possess a bandgap of approximately 1.0 eV that is further current matched to the other series connected solar cells. The dilute III-V nitride solar cell includes pair of contact blocking layers positioned on opposite surfaces of its p-n junction to improve the electron and hole collection efficiency of the p-n junction by preventing the flow of electrons and holes, respectively, into the adjacent layers of the multijunction solar cell in certain directions, depending upon the orientation of the p-n junction, so that electrons may only flow through the dilute III-V nitride solar cell in one direction while holes may only flow through the dilute III-V nitride solar cell in the opposite direction. The blocking layers and dilute III-V nitride absorber layers are lattice matched. The N composition in the dilute III-V nitride absorber layers is further graded so as to promote the collection of electron or holes in both the p- and n-type absorber layers.

While a multijunction solar cell having a dilute Group III-V nitride solar cell with contact blocking layers has been described in terms of what are presently considered to be the most practical and preferred embodiments, it is to be understood that the present disclosure need not be limited to the above embodiments. It should also be understood that a variety of changes may be made without departing from the essence of the disclosed subject matter. For example, materials other than those described in the various embodiments may be utilized for the various layers of the multijunction solar cell as long as they provide the desired characteristics achieved by the materials described in the various embodiments. Such changes are also implicitly included in the description and still fall within the scope of the present disclosure. It should be understood that this disclosure is intended to yield one or more patents covering numerous aspects of the invention both independently and as an overall system and in both method and apparatus modes.

Further, each of the various elements of the invention and claims may also be achieved in a variety of manners. This disclosure should be understood to encompass each such variation, be it a variation of an embodiment of any apparatus embodiment, a method or process embodiment, or even merely a variation of any element of these. Particularly, it should be understood that the words for each element of the invention may be expressed by equivalent apparatus terms or method terms. Such equivalent, broader, or even more generic terms should be considered to be encompassed in the description of each element or action. Such terms can be substituted where desired to make explicit the implicitly broad coverage to which this invention is entitled.

It should be understood that all actions may be expressed as a means for taking that action or as an element which causes that action. Similarly, each physical element disclosed should be understood to encompass a disclosure of the action which that physical element facilitates. The above is intended to cover various modifications and similar arrangements included within the spirit and scope of the below appended claims, the scope of which should be accorded the broadest interpretation so as to encompass all such modifications and similar structures and/or method steps. Therefore, the present invention includes any and all embodiments of the following below appended claims.

1. A multijunction solar cell comprising:
a plurality of a p-n junction solar cells connected in series with one another;
wherein one of the plurality of a p-n junction solar cells comprises a dilute Group III-V nitride solar cell having contact blocking layers formed on opposing sides of the p-n junction that prevent the passage of electrons in one direction from the dilute Group III-V nitride solar cell into an adjacent layer of the multijunction solar cell and prevent the passage of holes in an opposing direction from the dilute Group III-V nitride solar cell into an adjacent layer of the multijunction solar cell.

2. The multijunction solar cell of claim 1, wherein the dilute Group III-V nitride solar cell includes a p-n junction formed by respective p-type and n-type layers of a dilute Group III-V nitride material.

3. The multijunction solar cell of claim 2, wherein the p-type and n-type layers of dilute Group III-V nitride material comprise GaNAs, GaInNAs or GaNSbAs.

4. The multijunction solar cell of claim 3, wherein the p-type and n-type layers of material comprise GaNAs (or GaInNAs, GaNSbAs) with nitrogen concentration ranging from 0.5-5%.

5. The multijunction solar cell of claim 2, wherein at least one of the p-type and n-type layers have a compositionally graded nitrogen concentrations to provide an electric field for more efficient charge collection.

6. The multijunction solar cell of claim 2, wherein at least one of the contact blocking layers is lattice matched to corresponding band gaps of the p-type or n-type layers.

7. The multijunction solar cell of claim 2, wherein a conduction band of at least one of the contact blocking layers is aligned with a corresponding sub-band of an adjacent one of the p-type or n-type layers.

8. The multijunction solar cell of claim 1, wherein the contact blocking layers comprise at least one of AlGaAs, InGaP or another group III-V ternary alloy.

9. The multijunction solar cell of claim 1, wherein the dilute Group III-V nitride solar cell is current matched to the other plurality of a p-n junction solar cells of the multijunction solar cell such that each of the p-n junction solar cells connected in series produces substantially the same current when exposed to solar radiation.

10. The multijunction solar cell of claim 1, wherein the dilute Group III-V nitride solar cell is formed to possess a bandgap of approximately 1.0 eV.

11. The multijunction solar cell of claim 1, wherein the nitrogen composition in dilute Group III-V nitride solar cell can be tuned to a bandgap of 0.8-1.4 eV so that it can be used as part of a multijunction cell with various number of junctions.

12. The multijunction solar cell of claim 1, wherein the dilute Group III-V nitride solar cell further includes a protective layer formed on one of the contact blocking layers to provide a protective covering and further provide a low resistance electrical contact.

13. A dilute Group III-V nitride solar cell for a multijunction solar cell, comprising:
a p-n junction formed by respective p-type and n-type layers of a dilute Group III-V nitride material, wherein each of the p-type and n-type layers possess an inner surface adjacent to a junction formed between the p-type and n-type layers and an outer surface on an opposite side of the p-type and n-type layers from the junction;
a first contact blocking layer formed on an outer surface of the p-type layer of dilute Group III-V nitride material;
a second contact blocking layer formed on an outer surface of the n-type layer of dilute Group III-V nitride material;
wherein the first and second contact blocking layers are arranged to prevent the passage of electrons in one direction from the dilute Group III-V nitride solar cell and prevent the passage of holes in an opposing direction from the dilute Group III-V nitride solar cell.

14. The solar cell of claim 12, wherein the p-type and n-type layers of dilute Group III-V nitride material comprise GaNAs (or GaInNAs, GaNSbAs).

15. The solar cell of claim 13, wherein the p-type and n-type layers of material comprise GaNAs (or GaInNAs, GaNSbAs) with nitrogen concentration ranging from 0.5-5%.

16. The solar cell of claim 12, wherein at least one of the p-type and n-type layers have a compositionally graded nitrogen concentrations to provide an electric field for more efficient charge collection.

17. The solar cell of claim 12, wherein at least one of the contact blocking layers is lattice matched to corresponding band gaps of the p-type or n-type layers.

18. The solar cell of claim 12, wherein a conduction band of at least one of the contact blocking layers is aligned with a corresponding sub-band of an adjacent one of the p-type or n-type layers.

19. The solar cell of claim 12, wherein the contact blocking layers comprise at least one of AlGaAs, InGaP or another group III-V ternary alloy.

20. The solar cell of claim 12, wherein the dilute Group III-V nitride solar cell is formed to possess a bandgap of approximately 1.0 eV.

21. The solar cell of claim 12, wherein the dilute Group III-V nitride solar cell further includes a protective layer formed on one of the contact blocking layers to provide a protective covering and further provide a low resistance electrical contact.
